(19) United States
(12) Patent Application Publication
(10) Pub. No.: US 2024/0413286 A1
(43) Pub. Date: Dec. 12, 2024

(54) DISPLAY DEVICE

(71) Applicants: InnoLux Corporation, Miao-Li County (TW); CARUX TECHNOLOGY PTE. LTD., SINGAPORE (SG)

(72) Inventors: Li-Wei SUNG, Tainan (Tainan Science Park) (TW); Chieh-Tse YANG, Tainan (Tainan Science Park) (TW); Hsin-Cheng CHEN, Miao-Li County (TW)

(21) Appl. No.: 18/658,068

(22) Filed: May 8, 2024

(30) Foreign Application Priority Data
Jun. 7, 2023 (CN) 202310668560.3

(51) Int. Cl. H01L 33/62; H01L 25/075; H01L 33/64

(52) U.S. Cl. CPC H01L 33/62; H01L 25/0753; H01L 33/642

(57) ABSTRACT

Display devices are provided. The display device includes a substrate, a plurality of light-emitting elements, a back plate, and a carrier. The substrate has a first thermal expansion coefficient. The plurality of light-emitting elements is disposed on the substrate. The back plate is disposed corresponding to the substrate and has a second thermal expansion coefficient. The carrier is disposed between the substrate and the back plate and has a third thermal expansion coefficient. The absolute value of the difference between the third thermal expansion coefficient and the first thermal expansion coefficient is less than or equal to the absolute value of the difference between the third thermal expansion coefficient and the second thermal expansion coefficient.

### CROSS REFERENCE TO RELATED APPLICATIONS

This application claims priority of China Patent Application No. 202310668560.3, filed on Jun. 7, 2023, the entirety of which is incorporated by reference herein.

### TECHNICAL FIELD

Some embodiments of the present disclosure relate to a display device, and, in particular, to a display device including a carrier.

### BACKGROUND

Electronic products that include display devices, such as displays, smartphones, tablets, notebook computers, and televisions, have become indispensable necessities in modern society. With the booming development of this type of electronic product, consumers have high expectations for the quality, functionality, or price of these electronic products.

Typically, display devices include multiple films, layers, and/or elements. However, the connection between multiple films, layers, and/or elements can affect the structural strength of the display device. Therefore, these electronic products do not meet consumer expectations in all respects, and there are still some problems with electronic products. The development of display devices that can improve the connection between multiple films, layers, and/or elements is still one of the current goals.

### SUMMARY

In some embodiments, a display device is provided. The display device includes a substrate, a plurality of light-emitting elements, a back plate, and a carrier. The substrate has a first thermal expansion coefficient. The plurality of light-emitting elements is disposed on the substrate. The back plate is disposed corresponding to the substrate and has a second thermal expansion coefficient. The carrier is disposed between the substrate and the back plate and has a third thermal expansion coefficient. The absolute value of the difference between the third thermal expansion coefficient and the first thermal expansion coefficient is less than or equal to the absolute value of the difference between the third thermal expansion coefficient and the second thermal expansion coefficient.

In some embodiments, a display device is provided. The display device includes a substrate, a plurality of light-emitting elements, a back plate, and a carrier. The substrate has a first thermal expansion coefficient. The plurality of light-emitting elements is disposed on the substrate. The back plate is disposed corresponding to the substrate and has a second thermal expansion coefficient. The carrier is disposed between the substrate and the back plate and has a third thermal expansion coefficient. The third thermal expansion coefficient is between the first thermal expansion coefficient and the second thermal expansion coefficient.

The display devices of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 shows a schematic cross-sectional view of a display device according to some embodiments of the present disclosure.

FIG. 2A to 2D show schematic top views of a first adhesive layer according to some embodiments of the present disclosure, respectively.

FIG. 3 shows a schematic top view of a display device according to some embodiments of the present disclosure.

FIG. 4 shows a schematic top view of a back plate according to some embodiments of the present disclosure.

FIG. 5 shows a schematic cross-sectional view of a display device according to some embodiments of the present disclosure.

FIG. 6 shows a schematic cross-sectional view of a display device according to some embodiments of the present disclosure.

FIG. 7 shows a schematic top view of a display device according to some embodiments of the present disclosure.

FIG. 8 shows a schematic cross-sectional view of a display device according to some embodiments of the present disclosure.

FIG. 9 shows a schematic cross-sectional view of a display device according to some embodiments of the present disclosure.

FIG. 10A to 10E show schematic top views of an second adhesive layer according to some embodiments of the present disclosure, respectively.

### DETAILED DESCRIPTION

Display devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar and/or corresponding reference numerals may be used in different embodiments to designate similar and/or corresponding elements in order to clearly describe the present disclosure. However, the use of these similar and/or corresponding reference numerals is only for the purpose of simply and clearly description of some embodiments of the present disclosure, and does not imply any correlation between the different embodiments and/or structures discussed.

It should be understood that relative terms, such as “lower”, “bottom”, “higher” or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second” and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to connection and bonding can also include embodiments in which both structures are movable, or in which both structures are fixed. Furthermore, the terms “electrically connected” or “electrically coupled” include any direct and indirect means of electrical connection.

Herein, the terms “about”, “approximately”, and “substantially” generally mean within 10%, within 5%, within 3%, within 2%, within 1%, or within 0.5% of a given value or range. The given value is an approximate value, that is, “about”, “approximately”, and “substantially” can still be implied without the specific description of “about”, “approximately”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 1% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in this disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “comprising”, “including”, and “having” are open-ended words, so they should be interpreted as meaning “including but not limited to . . . ”. Therefore, when the terms “comprising”, “including”, and/or “having” is used in the description of the present disclosure, it designates the presence of corresponding features, regions, steps, operations, and/or elements, but does not exclude the presence of one or more corresponding features, regions, steps, operations, and/or elements.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (width direction), the Y-axis direction is the second direction D2 (length direction), and the Z-axis direction is the third direction D3 (height direction). In some embodiments, the schematic cross-sectional views described herein are schematic views observing the XZ plane or YZ plane. In some embodiments, the schematic top views described herein are schematic views observing the XY plane.

It should be understood that, according to the embodiments of the present disclosure, the depth, the thickness, the width, or the height of each element, as well as the space or distance between elements, may be measured using an optical microscope (OM), a scanning electron microscope (SEM), a film thickness profiler (α-step), an ellipsometer, or another suitable method. In detail, according to some embodiments, a cross-sectional structure image including an element to be measured may be obtained by using the scanning electron microscope, and then the depth, the thickness, the width, or the height of each element, and the spacing or the distance between elements, may be measured.

It should be understood that, according to the embodiments of the present disclosure, material analysis and/or elemental analysis may be performed on an element by infrared spectroscopy (IR), energy-dispersive X-ray spectroscopy (EDS), or another suitable method to obtain the composition of the element. Then, the corresponding thermal expansion coefficient (coefficient of thermal expansion. CTE) of the obtained composition can be received by looking up a table, thereby obtaining the thermal expansion coefficient of the element. The thermal expansion coefficient of the element affects the expansion and contraction degree of the element, such as deformation. When the thermal expansion coefficient of the element is greater, the deformation of the element with temperature is greater, and when the thermal expansion coefficient of the element is smaller, the deformation of the element with temperature is smaller.

In some embodiments, the electronic device of the present disclosure may include a display device, a back light device, an antenna device, a sensing device, or a titling device, but the present disclosure is not limited thereto. The electronic device may be a foldable or flexible electronic device. The display device may be a non-self-luminous display device or a self-luminous display device. The antenna device may be a liquid crystal antenna device or a non-liquid crystal antenna device. The sensing device may be a sensing device for sensing capacitance, light, heat, or ultrasonic waves, but the present disclosure is not limited thereto. The electronic element may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The titling device may be, for example, a display titling device or an antenna titling device, but the present disclosure is not limited thereto. It should be noted that, the electronic device can be any arrangement and combination of the foregoing, but the present disclosure is not limited thereto. Hereinafter, display devices are used to illustrate the content of the present disclosure, but the present disclosure is not limited thereto.

In addition, the shape of the electronic device may be rectangular, circular, polygonal, a shape with curved edges, or another suitable shape. The electronic device may have a peripheral system, such as a processing system, a driving system, a control system, a light source system, a shelf system, or the like to support the display device or titling device.

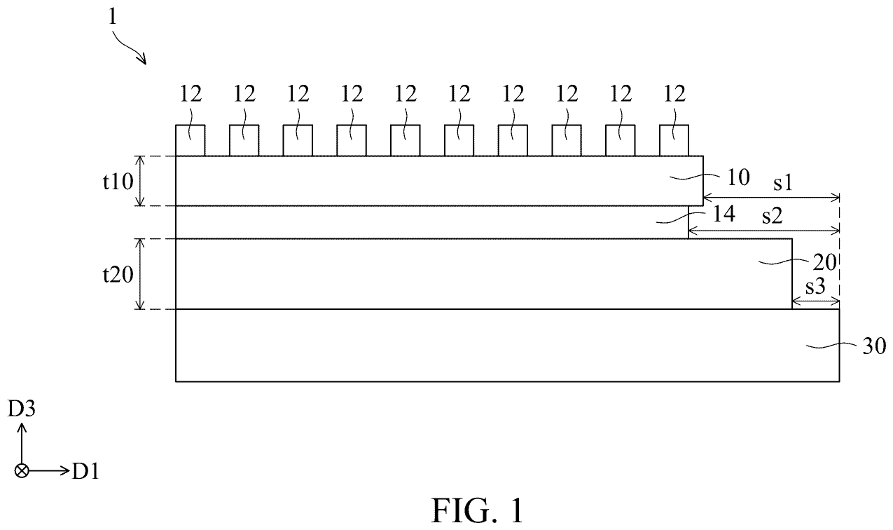

Referring to FIG. 1, a schematic cross-sectional view of a display device 1 according to some embodiments of the present disclosure is shown. It should be understood that, for clarity of explanation, some components of the display device 1 are omitted in the drawings, and some components are schematically illustrated. In some embodiments, additional components may be added to the display device 1 described below. In other embodiments, some components of the display device 1 described below may be replaced or omitted.

As shown in FIG. 1, in some embodiments, the display device 1 includes a substrate 10, a plurality of light-emitting elements 12, a carrier 20, and a back plate 30. In some embodiments, the substrate 10 may include a rigid substrate, a flexible substrate, or a combination thereof, but the present disclosure is not limited thereto. In some embodiments, the material of the substrate 10 may include or may be a wafer, glass, quartz, ceramics, sapphire, plastic, other suitable materials, or a combination thereof, but the present disclosure is not limited thereto. In some embodiments, the material of the substrate 10 may include or may be polycarbonate (PC), polyimide (PI), polypropylene (PP), polyethylene terephthalate (PET), other suitable materials, or a combination thereof, but the present disclosure is not limited thereto. In some embodiments, the substrate 10 may be a single-layer or multi-layer structure. In some embodiments, the substrate 10 may include or may be a transparent substrate, a translucent substrate, or an opaque substrate.

As shown in FIG. 1, the plurality of light-emitting elements 12 may be disposed on the substrate 10. The plurality of light-emitting elements 12 may be disposed on the substrate 10 in an array. For example, along the first direction D1 and/or the second direction D2, each of the plurality of light-emitting elements 12 may be disposed at intervals. In the present disclosure, the light emitting element 12 may include an organic light-emitting diodes (OLEDs), a mini light-emitting diodes (mini LEDs), a micro light-emitting diodes (micro LEDs), or a quantum dot light-emitting diodes (quantum dot LED), but the present disclosure is not limited thereto.

As shown in FIG. 1, the back plate 30 may be disposed corresponding to the substrate 10. For example, in the normal direction of the substrate 10 (that is, the third direction D3), the back plate 30 may be disposed below the substrate 10. In other words, the substrate 10 may be disposed between the light emitting element 12 and the back plate 30. In some embodiments, the back plate 30 may include metal, alloy, or a combination thereof, but the present disclosure is not limited thereto. For example, metals may include copper (Cu), aluminum (Al), molybdenum (Mo), silver (Ag), tin (Sn), tungsten (W), gold (Au), chromium (Cr), nickel (Ni), platinum (Pt), other suitable metals, the like, or a combination thereof, but the present disclosure is not limited thereto. For example, alloys may include magnesium alloys, aluminum alloys, magnesium-aluminum alloys, other suitable alloys, the like, or a combination thereof, but the present disclosure is not limited thereto. The back plate 30 may be formed by pressure casting, stamping processes, other suitable processes, the like, or a combination thereof, but the present disclosure is not limited thereto.

The display device 1 further includes a carrier 20. The risk of damage (such as cracking) to the substrate 10 during operation of the display device 1 may be reduced or prevented by disposing of the carrier 20, thereby improving the reliability of the display device 1. As shown in FIG. 1, in the normal direction of the substrate 10, the carrier 20 may be disposed below the substrate 10, so that the carrier 20 is disposed between the substrate 10 and the back plate 30. For example, the carrier 20 can resist or block the external force from the back plate 30, thereby protecting the substrate 10 from damage. In some embodiments, multiple temperature cycle tests (for example, 80 cycles, but the present disclosure is not limited thereto) may be performed at a temperature of about −40 degrees Celsius to 90 degrees Celsius in order to examine the risk of damage to the substrate 10.

In some embodiments, the carrier 20 may include metal, alloy, or a combination thereof, but the present disclosure is not limited thereto. For example, metals may include iron (Fe), carbon (C), chromium (Cr), nickel (Ni), titanium (Ti), manganese (Mn), aluminum (Al), molybdenum (Mo), and other suitable metals, the like, or a combination thereof, but the present disclosure is not limited thereto. For example, the alloy may include stainless steel, invar (also known as nickel steel alloy), other suitable alloys, the like, or a combination thereof, but the present disclosure is not limited thereto. In some embodiments, the carrier 20 may be formed by a stamping process, other suitable processes, the like, or a combination thereof, but the present disclosure is not limited thereto.

Components (such as the substrate 10, the carrier 20, and the back plate 30) made of different materials or elements will have different thermal expansion coefficients, so they will deform to different degrees in the same environment (for example, corresponding to the same high or low temperature conditions). In some embodiments, the risk of damage to the substrate 10 may be reduced by selecting suitable materials to form the corresponding substrate 10, carrier 20, and back plate 30. For example, the display device 1 may be formed by materials with a small difference between the thermal expansion coefficient CTE₁₀ of the substrate 10 and the thermal expansion coefficient CTE₂₀ of the carrier 20. In some embodiments, the difference between the thermal expansion coefficient CTE₂₀ of the carrier 20 and the thermal expansion coefficient CTE₁₀ of the substrate 10 (CTE₂₀−CTE₁₀) may be less than or equal to 7×10⁻⁶ K⁻¹ and greater than or equal to 0 K⁻¹. For example, the difference between the thermal expansion coefficient CTE₁₀ and the thermal expansion coefficient CTE₂₀ may be 7×10⁻⁶ K⁻¹, 6×10⁻⁶ K⁻¹, 5×10⁻⁶ K⁻¹, 4×10⁻⁶ K⁻¹, 3×10⁻⁶ K⁻¹, 2×10⁻⁶ K⁻¹, 1×10⁻⁶ K⁻¹, 0 K⁻¹, or any value or range of values between the abovementioned values, but the present disclosure is not limited thereto. For example, the carrier 20 may be stainless steel.

Accordingly, when the thermal expansion coefficient CTE₁₀ of the substrate 10 is close to the thermal expansion coefficient CTE₂₀ of the carrier 20, the deformations of the substrate 10 and the carrier 20 are close to each other, thereby preventing the substrate 10 from damaging due to excessive deformation differences between the substrate 10 and components adjacent to the substrate 10. Therefore, the risk of damage to the substrate 10 may be reduced by the carrier 20.

In some embodiments, the thermal expansion coefficient CTE₂₀ of the carrier 20 may be between the thermal expansion coefficient CTE₁₀ of the substrate 10 and the thermal expansion coefficient CTE₃₀ of the back plate 30, thereby reducing the risk of damage to the substrate 10. For example, compared to the direct contact between the substrate 10 and the back plate 30, the carrier 20 having the thermal expansion coefficient CTE₂₀ between the thermal expansion coefficient CTE₁₀ and the thermal expansion coefficient CTE₃₀ may be used as an intermediate material. Therefore, the carrier 20 disposed between the substrate 10 and the back plate 30 can prevent the substrate 10 from being damaged due to excessive deformation differences between the substrate 10 and components adjacent to the substrate 10. In some embodiments, the absolute value of the difference between the thermal expansion coefficient CTE₁₀ and the thermal expansion coefficient CTE₂₀ is less than or equal to the absolute value of the difference between the thermal expansion coefficient CTE₂₀ and the thermal expansion coefficient CTE₃₀ (that is, |CTE 10−CTE 20|≤|CTE 20−CTE 30|). By improving the matching degree between the substrate 10 and the carrier 20, the substrate 10 and the carrier 20 may better resist or block the external force from the back plate 30, thereby reducing the risk of damage to the substrate 10. In some embodiments, the thermal expansion coefficient CTE₂₀ of the carrier 20 may be greater than or equal to the thermal expansion coefficient CTE₁₀ of the substrate 10 and may be less than or equal to the thermal expansion coefficient CTE₃₀ of the back plate 30. For example, the carrier 20 may include stainless steel.

In some embodiments, the carrier 20 may have a low thermal expansion coefficient, so that the carrier 20 does not substantially deform with temperature, or the deformation degree along with temperature changes is reduced. Accordingly, the carrier 20 can block the influence of different deformations of the substrate 10 and the back plate 30. In some embodiments, the carrier 20 may, for example, have the lowest thermal expansion coefficient, and the absolute value of the difference between the thermal expansion coefficient CTE₁₀ and the thermal expansion coefficient CTE₂₀ is less than or equal to the absolute value of the difference between the thermal expansion coefficient CTE₂₀ and the thermal expansion coefficient CTE₃₀ (That is, |CTE₁₀−CTE₂₀|≤|CTE₂₀−CTE₃₀|). In some embodiments, the thermal expansion coefficient CTE₂₀ of the carrier 20 may be less than or equal to 4.5×10⁻⁶ K⁻¹. For example, the thermal expansion coefficient CTE₂₀ of the carrier 20 may be less than or equal to 4.5×10⁻⁶ K⁻¹, 4.3×10⁻⁶ K⁻¹, 4×10⁻⁶ K⁻¹, 3.5×10⁻⁶ K⁻¹, 3×10⁻⁶ K⁻¹, 2.5×10⁻⁶ K⁻¹, 2×10⁻⁶ K⁻¹, 1.5×10⁻⁶ K⁻¹, 1×10⁻⁶ K⁻¹, 5×10⁻⁷ K⁻¹, or any value or range of values between the abovementioned values, but the present disclosure is not limited thereto. When the deformation of the carrier 20 disposed between the substrate 10 and the back plate 30 is low, the substrate 10 may be prevented from being affected by the deformation of the back plate 30, and the risk of damage to the substrate 10 may be reduced by the carrier 20. In other embodiments, the carrier 20 may include a material that does not substantially deform with temperature. For example, the carrier 20 may include Invar.

In some embodiments, the strength of the carrier 20 may be greater than the strength of the substrate 10, so the strength of the carrier 20 is sufficient to replace the substrate 10 to resist the deformation of the back plate 30. The strength may be compressive strength, tensile strength, yield strength, bending strength, or strength defined in other methods, but the present disclosure is not limited thereto. For example, the carrier 20 may include stainless steel.

As shown in FIG. 1, in the normal direction of the substrate 10, the substrate 10 has a first thickness t10, and the carrier 20 has a second thickness t20. When the display device 1 is a flat display device, since the deformation amount (single-dimensional deformation amount) of the substrate 10 and the carrier 20 is relatively low, the first thickness t10 of the substrate 10 and the second thickness t20 of the carrier 20 may be adjusted according to the usage requirements. When the display device 1 is a curved display device, since the deformation amount (multi-dimensional deformation amount) of the substrate 10 and the carrier 20 is relatively high, the ratio of the second thickness t20 of the carrier 20 and the first thickness t10 of the substrate 10 (the second thickness t20/the first thickness t10) may be less than or equal to 2. For example, the ratio of the second thickness t20 to the first thickness t10 may be 2, 1.9, 1.8, 1.7, 1.6, 1.5, 1.4, 1.3, 1.2, 1.1, 1, 0.9, 0.8, 0.7, 0.6, 0.5, 0.4, 0.33, 0.3, 0.2, 0.1, or any value or range of values between the abovementioned values, but the present disclosure is not limited thereto. In some embodiments, when the second thickness t20 of the carrier 20 is too small, it is difficult for the carrier 20 to effectively block the deformation of the substrate 10 and the back plate 30. When the second thickness t20 of the carrier 20 is too large, the carrier 20 is not easy to apply in display devices with curved surfaces.

In some embodiments, the plurality of light-emitting elements 12 may be formed on the substrate 10. Next, a first bonding process is performed to bond the substrate 10 and the carrier 20 by the first bonding element, so that the substrate 10 is disposed between the light-emitting element 12 and the carrier 20. Then, a second bonding process is performed to bond the carrier 20 and the back plate 30 by the second bonding element, so that the carrier 20 is disposed between the substrate 10 and the back plate 30. Accordingly, since the carrier 20 is disposed between the substrate 10 and the back plate 30, the process margin (process window) for performing the first bonding process and the second bonding process may be increased, making the bonding of the substrate 10 and the back plate 30 more flexible.

For example, the first bonding process and/or the second bonding process may use chemical bonding methods, physical bonding methods, or a combination thereof, but the present disclosure is not limited thereto. For example, the first bonding element and/or the second bonding element may include an adhesive layer, screws, buckles, slots, and other suitable bonding elements, the like, or a combination thereof, but the present disclosure is not limited thereto. Therefore, the carrier 20 can increase the breadth of choices of the first bonding element and the second bonding element.

As shown in FIG. 1, in some embodiments, the display device 1 further includes a first adhesive layer 14. In some embodiments, the first adhesive layer 14 is disposed between the substrate 10 and the carrier 20. In some embodiments, the first adhesive layer 14 may be used as a first bonding element to connect the substrate 10 and the carrier 20. In some embodiments, the first adhesive layer 14 may include organic materials or inorganic materials. In some embodiments, the first adhesive layer 14 may include solid adhesive, liquid adhesive, other suitable adhesive materials, the like, or a combination thereof, but the present disclosure is not limited thereto. For example, the solid adhesive may include double sided tape with base material or double sided tape without base material, and wherein the base material may be poly(ethyl benzene-1,4-dicarboxylate) (PET), composite materials, other suitable substrates, the like, or a combination thereof, but the present disclosure is not limited thereto. For example, the liquid adhesive may include pressure sensitive adhesives (PSA), silicon-based adhesives such as epoxy resin, other suitable liquid adhesive materials, the like, or a combinations thereof, but the present disclosure is not limited thereto. In other embodiments, the first adhesive layer 14 may be replaced or partially replaced (that is, used in combination) with screws, buckles, slots, other suitable bonding elements, or the like. In some embodiments, the first adhesive layer 14 may be formed by spin coating, dispensing, pasting, other suitable methods, or a combination thereof.

As shown in FIG. 1, in the first direction D1, the edge of the substrate 10 is separated from the edge of the back plate 30 by a distance s1, the edge of the first adhesive layer 14 is separated from the edge of the back plate 30 by a distance s2, and the edge of the carrier 20 is separated from the edge of the back plate 30 by a distance s3. The area of the carrier 20 may be greater than the area of the substrate 10, so that the distance s3 may be smaller than the distance s1. Therefore, it is beneficial to bond the carrier 20 and the substrate 10, thereby reducing the risk of damage to the substrate 10, improving the bonding margin between the carrier 20 and the substrate 10, and/or improving the reliability of the display device 1. In some embodiments, the area of the carrier 20 may be smaller than the area of the back plate 30. In some embodiments, the area of the first adhesive layer 14 may be smaller than the area of the substrate 10, so that the distance s2 may be greater than the distance s1.

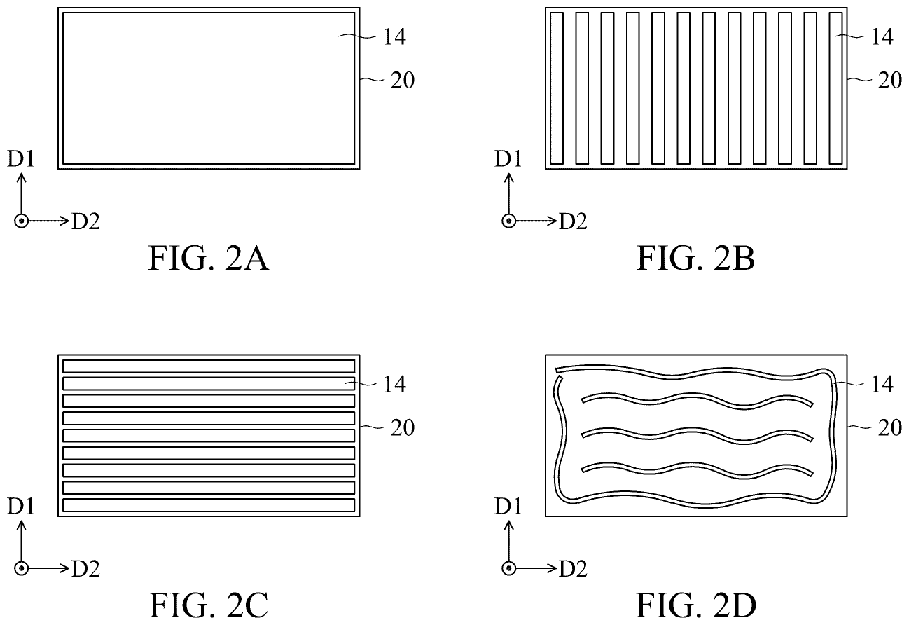

Referring to FIGS. 2A to 2D, top views of the first adhesive layer 14 and the carrier 20 according to some embodiments of the present disclosure are respectively shown. For ease of explanation, FIGS. 2A to 2D show the first adhesive layer 14 and the carrier 20, and other components are omitted. It should be noted that, one or more of the first adhesive layers 14 shown in FIGS. 2A to 2D may be combined with any display device (for example, the display device 1 and/or the display devices 2, 3, and/or 4 described below). As shown in FIG. 2A, the first adhesive layer 14 is disposed on the carrier 20 in a block shape. As shown in FIG. 2B and FIG. 2C, the first adhesive layer 14 is disposed on the carrier 20 in a strip shape. For example, the first adhesive layer 14 may extend along the first direction D1 and be spaced apart along the second direction D2. Alternatively, the first adhesive layer 14 may extend along the second direction D2 and be spaced apart along the first direction D1. As shown in FIG. 2D, the first adhesive layer 14 may be disposed on the carrier 20 in any shape. For example, the first adhesive layer 14 may have linear shape, curved shape, annular shape, wavy shape, other suitable shapes, the like, or a combination thereof.

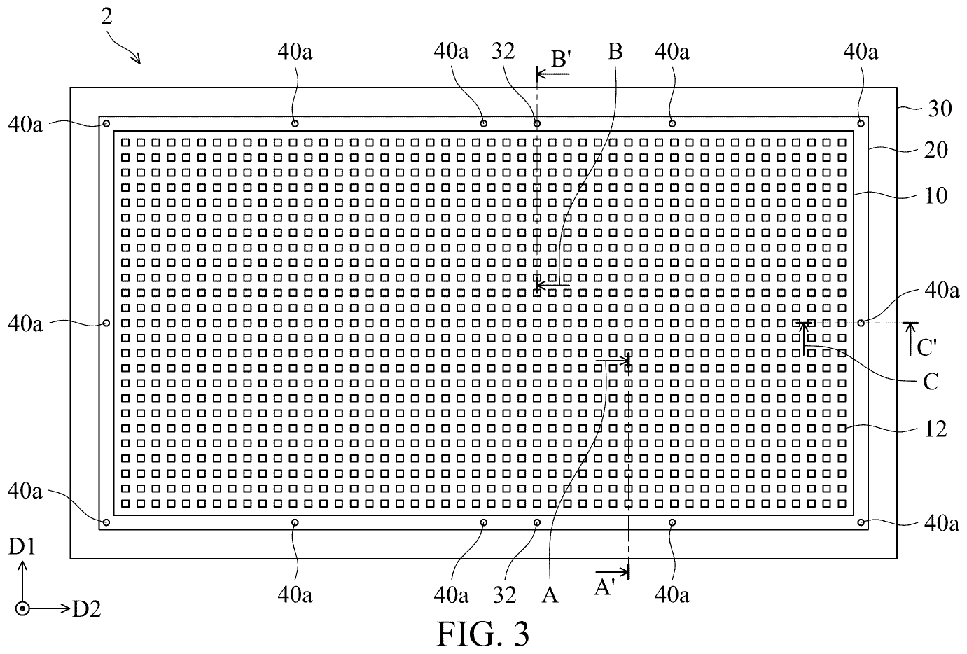

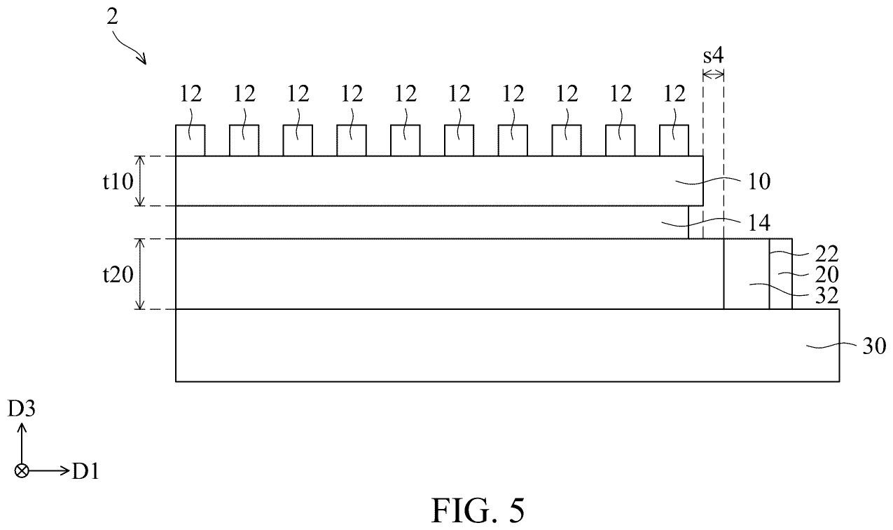

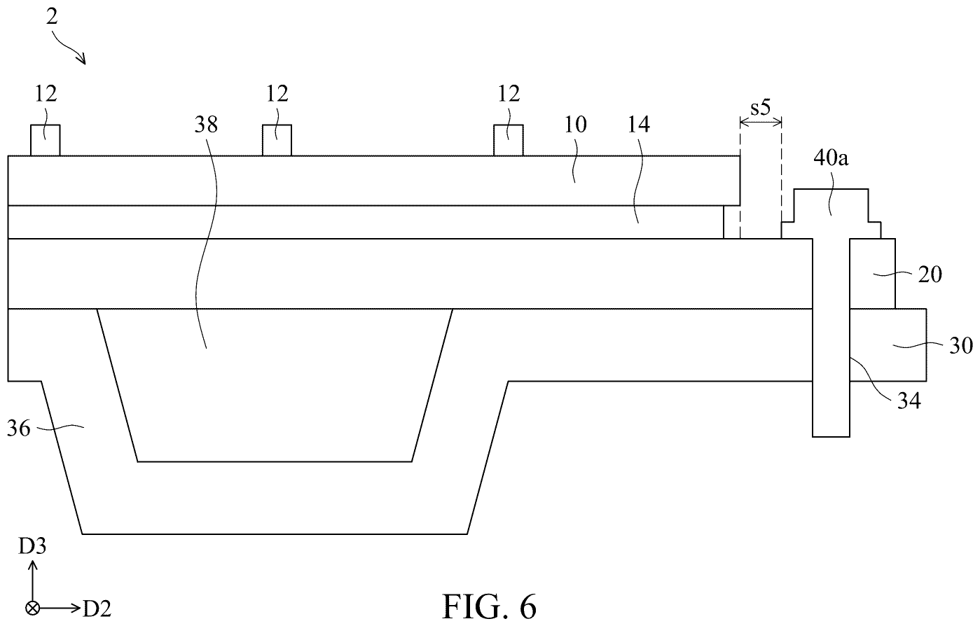

Referring to FIG. 3, a schematic top view of a display device 2 according to some embodiments of the present disclosure is shown. The cross-sectional view taken along the line segment A-A′ shown in FIG. 3 is similar to the cross-sectional view shown in FIG. 1, the cross-sectional view taken along the line segment B-B′ shown in FIG. 3 is shown in FIG. 5, and the cross-sectional view taken along line segment C-C′ as shown in FIG. 3 is shown in FIG. 6. As shown in FIG. 3, in the normal direction of the substrate 10, the carrier 20 may be disposed on the back plate 30, the substrate 10 may be disposed on the carrier 20, and the plurality of light-emitting elements 12 may be disposed on the substrate 10.

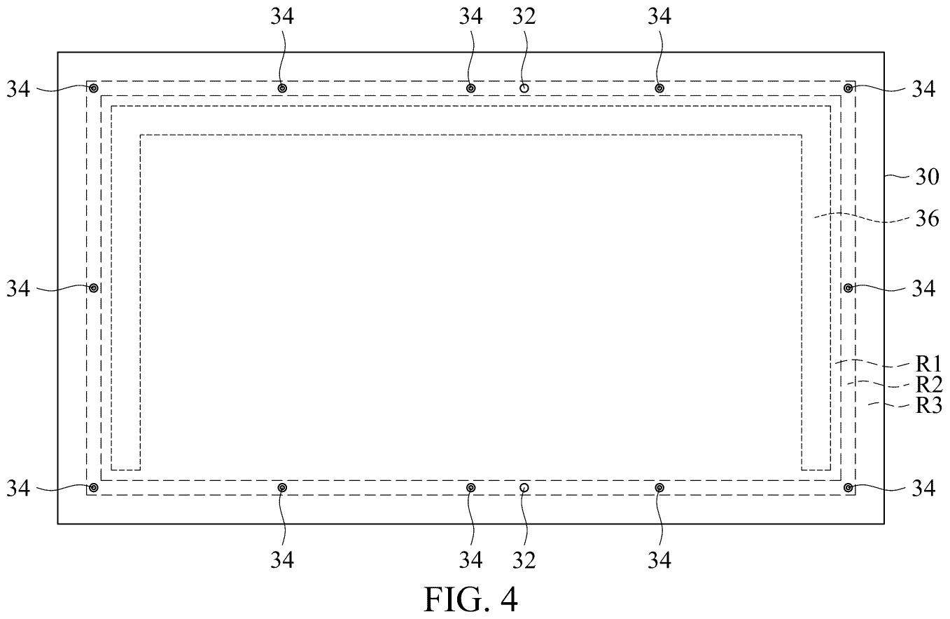

FIG. 4 shows a schematic top view of the back plate 30 according to some embodiments of the present disclosure. As shown in FIG. 4, the back plate 30 may include a first region R1 that overlaps the substrate 10 in the third direction D3, a second region R2 that overlaps the carrier 20 and does not overlap the substrate 10 in the third direction D3, and the remaining third region R3. In some embodiments, the back plate 30 may further include a limiting element 32, a hole 34, and/or a recess 36, and the limiting element 32, the hole 34, and/or the recess 36 will be described in conjunction with the subsequent drawings.

FIG. 5 shows a schematic cross-sectional view of the display device 2 according to some embodiments of the present disclosure. As shown in FIGS. 3 to 5, the back plate 30 may further include the limiting element 32 disposed on the back plate 30 to correspond to the carrier 20. The limiting element 32 may be disposed in the second region R2 of the back plate 30 (as shown in FIGS. 3 to 5) or may be disposed in at least a portion of the periphery of the second region R2, so that the alignment accuracy during bonding the back plate 30 and the carrier 20 may be improved. In some embodiments, the limiting element 32 may be a bump, and the limiting element 32 may have a cylindrical shape, a corner prism shape, a rectangular prism shape, other suitable shapes, or a combination thereof, but the present disclosure is not limited thereto. In some embodiments, the carrier 20 may have a hole 22 corresponding to the limiting element 32, so that the limiting element 32 can penetrate the carrier 20 through the hole 22 to connect the back plate 30 and the carrier 20, thereby reducing sliding and alignment difficulties of the back plate 30 and the carrier 20. In some embodiments, in the first direction D1, the limiting element 32 is spaced apart from the edge of the substrate 10 by a distance s4 to prevent damaging the substrate 10 during the process of disposing the limiting element 32. For example, compared with disposing holes in the substrate 10 and damaging the substrate 10, disposing the holes 22 in the carrier 20 can reduce the risk of damage to the substrate 10.

FIG. 6 shows a schematic cross-sectional view of the display device 2 according to some embodiments of the present disclosure. As shown in FIGS. 3, 4, and 6, the display device 2 may further include a connecting element 40a, and the back plate 30 may further include a hole 34 disposed in the second region R2, so that the hole 34 of the back plate 30 corresponds to the connecting element 40a, thereby connecting the back plate 30 and the carrier 20. In some embodiments, the connecting element 40a may be a screw to provide two-dimensional fixation. In some embodiments, in the second direction D2, the connecting element 40a is spaced apart from the edge of the substrate 10 by a distance s5 to prevent damaging the substrate 10 during the process of disposing the connecting element 40a or to prevent the connecting element 40a from covering the light-emitting element 12. In some embodiments, the back plate 30 may further include a recess 36 disposed in the first region R1, and the recess 36 may serve as a reinforcing rib of the back plate 30. In some embodiments, the display device 2 may include an air gap 38 disposed in the recess 36, and the air gap 38 is between the back plate 30 and the carrier 20. In some embodiments, at least one of the plurality of light emitting elements 12 may overlap the air gap 38.

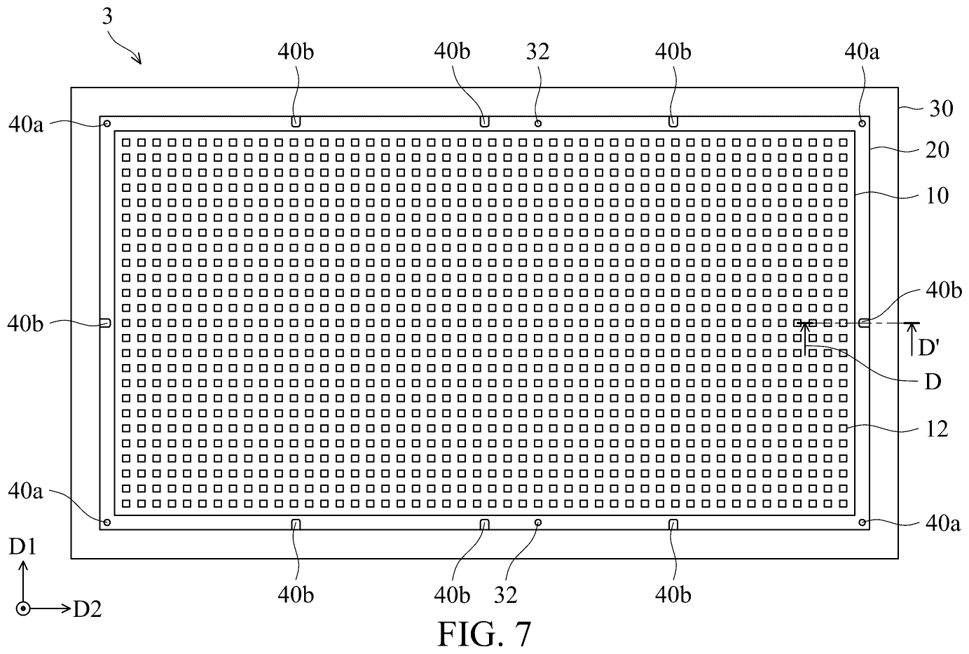

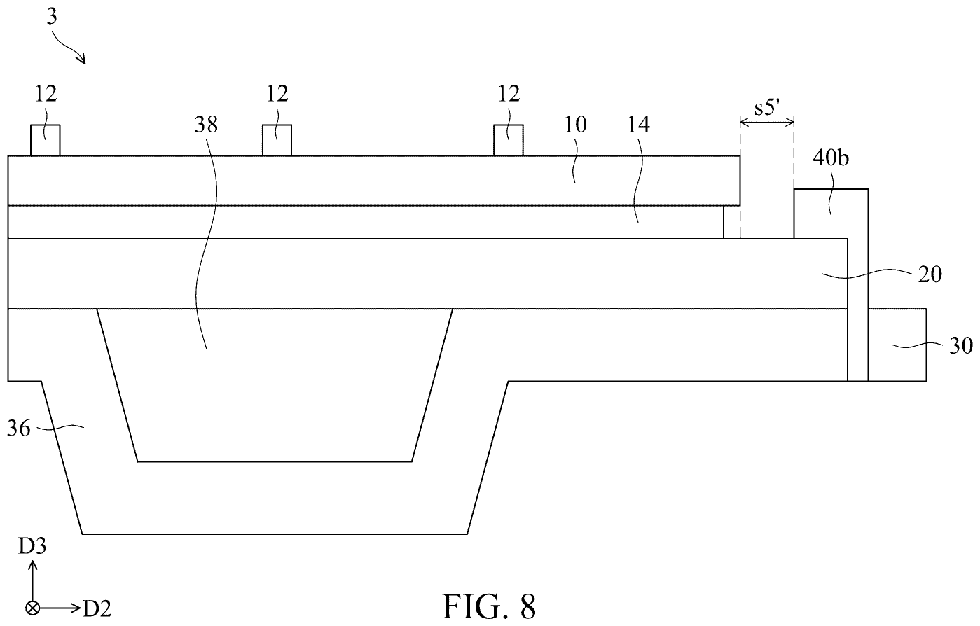

Referring to FIG. 7, a schematic top view of a display device 3 according to some embodiments of the present disclosure is shown. The cross-sectional view taken along the line segment D-D′ shown in FIG. 7 is shown in FIG. 8. Referring to FIG. 8, a schematic cross-sectional view of the display device 3 according to some embodiments of the present disclosure is shown. In some embodiments, the display device 3 may further include a connecting element 40b to connect the back plate 30 and the carrier 20. In some embodiments, connecting element 40b may serve as a second bonding element. The connecting element 40b may be disposed on the carrier 20 and cover the side surface and the top surface of the carrier 20. In some embodiments, the connecting element 40b may include a buckle. In some embodiments, the connecting element 40b and the back plate 30 may be integrally formed, so that the back plate 30 and the carrier 20 are connected by the curved portion of the back plate 30 (that is, the connecting element 40b) to provide three-dimensional fixation. In some embodiments, in the second direction D2, the connecting element 40b is spaced apart from the edge of the substrate 10 by a distance s5′ to prevent damaging the substrate 10 during the process of disposing the connecting element 40b or to prevent the connecting element 40b from covering the light-emitting element 12. In some embodiments, the display device 3 may include a limiting element 32, a connecting element 40a, a connecting element 40b, or a combination thereof, but the present disclosure is not limited thereto. For example, the corners of the back plate 30 may be provided with connecting elements 40a, and the sides of the back plate 30 may be provided with limiting elements 32 and connecting elements 40b.

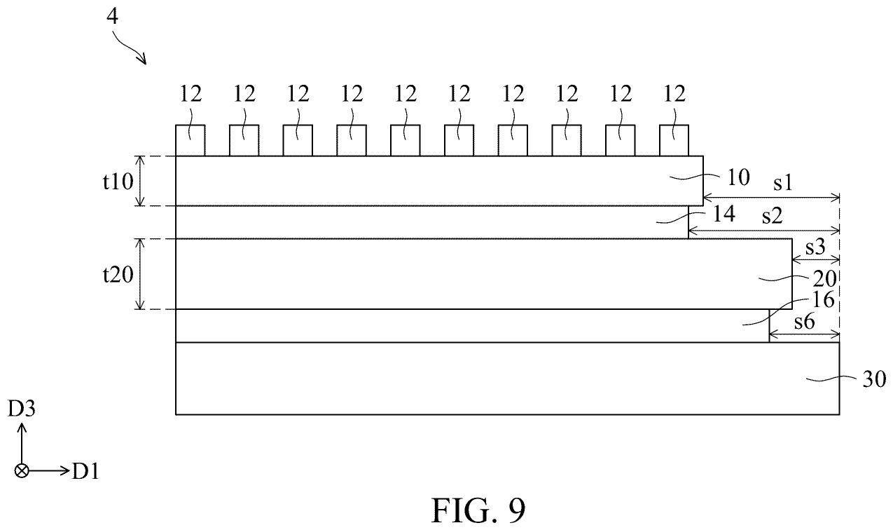

FIG. 9 shows a schematic cross-sectional view of the display device 4 according to some embodiments of the present disclosure. In some embodiments, the display device 4 further includes a second adhesive layer 16. In some embodiments, the second adhesive layer 16 is disposed between the carrier 20 and the back plate 30. In some embodiments, the second adhesive layer 16 may serve as a second bonding element. The second adhesive layer 16 may be replaced or partially replaced (that is, used in combination) with screws, buckles, slots, other suitable bonding elements, or the like to connect the carrier 20 and the back plate 30. In some embodiments, the material and formation method of the second adhesive layer 16 may be the same as or different from the materials and formation method of the first adhesive layer 14, so the descriptions will be omitted. In some embodiments, the edge of the second adhesive layer 16 is spaced apart from the edge of the back plate 30 by a distance s6. The area of the second adhesive layer 16 may be smaller than the area of the carrier 20, so that the distance s6 may be greater than the distance s3.

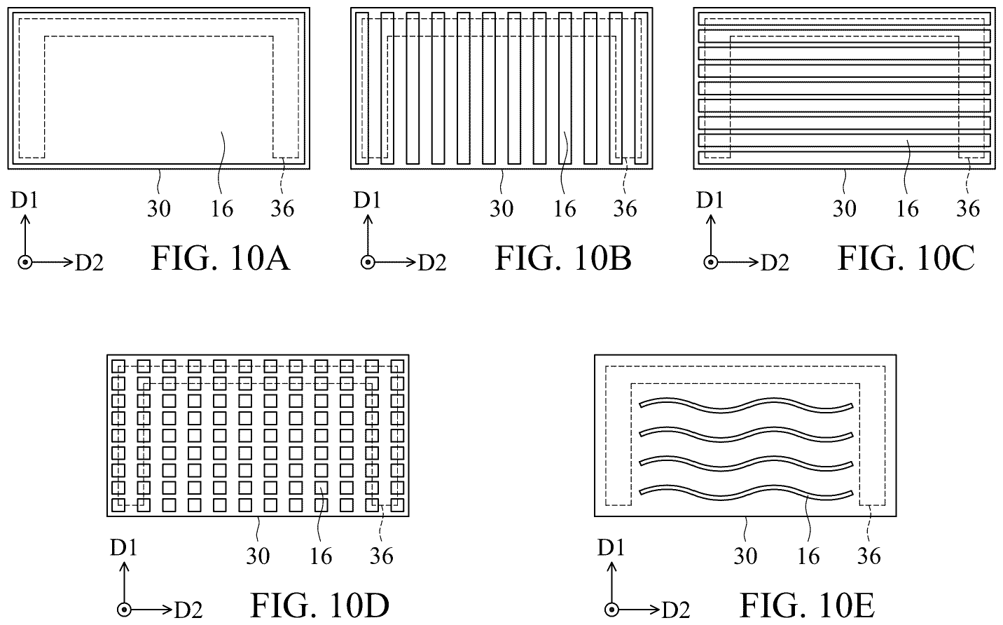

FIGS. 10A to 10E respectively show top views of the second adhesive layer 16 and the back plate 30 according to some embodiments of the present disclosure. For ease of explanation, FIGS. 10A to 10E show the second adhesive layer 16 and the back plate 30, and other components are omitted. It should be noted that, one or more of the second adhesive layers 16 shown in FIGS. 10A to 10E may be used in combination with any display device (for example, display devices 1, 2, 3, and/or 4). The arrangements of the second adhesive layer 16 shown in FIGS. 10A to 10E are similar to those in FIGS. 2A to 2D, so the descriptions will be omitted. The second adhesive layer 16 may be disposed on the back plate 30 in a block shape (FIG. 10A), in a strip shape (FIG. 10B and FIG. 10C), in an array (FIG. 10D), or in an arbitrary shape (FIG. 10E). In some embodiments, the second adhesive layer 16 may be spaced apart from the recess 36.

In summary, according to embodiments of the present disclosure, a display device is provided. The risk of damage to the substrate is reduced by disposing the carrier between the substrate and the back plate, thereby improving the reliability of the display device. In detail, the risk of damage to the substrate is reduced by adjusting the thermal expansion coefficient of the carrier, the relationship between the thermal expansion coefficients of the carrier and other components, and/or the strength of the carrier. Furthermore, since the carrier is disposed between the substrate and the back plate, the breadth of choices of the first bonding element (for example, the first adhesive layer 14) between the substrate and the carrier and the second bonding element (for example, the second adhesive layer 16, the connecting element 40a, the connecting element 40b) between the carrier and the back plate may be improved.

The features among the various embodiments of the present disclosure may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the above-mentioned process, machine, manufacturing, material composition, device, method, and steps. The protection scope of the present disclosure shall be determined by the scope of the claims. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A display device, comprising:
a substrate having a first thermal expansion coefficient;
a plurality of light-emitting elements disposed on the substrate;
a back plate disposed corresponding to the substrate and having a second thermal expansion coefficient; and
a carrier disposed between the substrate and the back plate and having a third thermal expansion coefficient;
wherein an absolute value of a difference between the third thermal expansion coefficient and the first thermal expansion coefficient is less than or equal to an absolute value of a difference between the third thermal expansion coefficient and the second thermal expansion coefficient.

2. The display device as claimed in claim 1, further comprising:
a first adhesive layer disposed between the substrate and the carrier.

3. The display device as claimed in claim 1, wherein the difference between the third thermal expansion coefficient and the first thermal expansion coefficient is less than or equal to 7×10⁻⁶ K⁻¹ and greater than or equal to 0 K⁻¹.

4. The display device as claimed in claim 1, wherein the third thermal expansion coefficient of the carrier is less than or equal to 4.5×10⁻⁶ K⁻¹.

5. The display device as claimed in claim 1, wherein the substrate has a first thickness, the carrier has a second thickness, and a ratio of the second thickness to the first thickness is less than or equal to 2.

6. The display device as claimed in claim 1, wherein the back plate further comprises:
a limiting element penetrating the carrier through a hole to connect the back plate and the carrier.

7. The display device as claimed in claim 6, wherein the limiting element is spaced apart from the substrate by a distance.

8. The display device as claimed in claim 1, further comprising:
a connecting element connecting the back plate and the carrier, wherein the connecting element is spaced apart from the substrate by a distance.

9. The display device as claimed in claim 1, wherein the back plate further comprises:
a recess, wherein an air gap is disposed in the recess and at least one of the plurality of light-emitting elements overlaps the air gap.

10. The display device as claimed in claim 1, wherein a strength of the carrier is greater than a strength of the substrate.

11. The display device as claimed in claim 1, wherein an area of the carrier is greater than an area of the substrate.

12. The display device as claimed in claim 1, further comprising:
a second adhesive layer disposed between the carrier and the back plate.

13. A display device, comprising:
a substrate having a first thermal expansion coefficient;
a plurality of light-emitting elements disposed on the substrate;
a back plate disposed corresponding to the substrate and having a second thermal expansion coefficient; and
a carrier disposed between the substrate and the back plate and having a third thermal expansion coefficient,
wherein the third thermal expansion coefficient is between the first thermal expansion coefficient and the second thermal expansion coefficient.

14. The display device as claimed in claim 13, wherein a difference between the third thermal expansion coefficient and the first thermal expansion coefficient is less than or equal to 7×10⁻⁶ K⁻¹ and greater than or equal to 0 K⁻¹.

15. The display device as claimed in claim 13, wherein an absolute value of the difference between the third thermal expansion coefficient and the first thermal expansion coefficient is less than or equal to an absolute value of a difference between the third thermal expansion coefficient and the second thermal expansion coefficient.

16. The display device as claimed in claim 13, wherein the substrate has a first thickness, the carrier has a second thickness, and a ratio of the second thickness to the first thickness is less than or equal to 2.

17. The display device as claimed in claim 13, wherein the back plate further comprises:
a limiting element penetrating a hole of the carrier to connect the back plate and the carrier.

18. The display device as claimed in claim 13, further comprising:
a connecting element connecting the back plate and the carrier, wherein the connecting element is spaced apart from the substrate by a distance.

19. The display device as claimed in claim 13, wherein the back plate further comprises:
a recess, wherein an air gap is disposed in the recess and at least one of the plurality of light-emitting elements overlaps the air gap.

20. The display device as claimed in claim 13, wherein a strength of the carrier is greater than a strength of the substrate.
